(19) United States
(12) Patent Application Publication
(10) Pub. No.: US 2023/0197623 A1
(43) Pub. Date: Jun. 22, 2023

(54) ELECTRONIC DEVICE INCLUDING AN INTEGRATED CIRCUIT DIE AND A SUPPORT STRUCTURE

(71) Applicant: Advanced Micro Devices, Inc., Santa Clara, CA (US)

(72) Inventors: Arsalan Alam, Austin, TX (US); Raja Swaminathan, Austin, TX (US); Rahul Agarwal, Livermore, CA (US)

(73) Assignee: Advanced Micro Devices, Inc., Santa Clara, CA (US)

(21) Appl. No.: 17/645,104

(22) Filed: Dec. 20, 2021

(51) Int. Cl. H01L 23/538; H01L 23/00; H01L 23/498

(52) U.S. Cl. CPC H01L 23/5384; H01L 24/14; H01L 23/49811; H01L 23/5385; H01L 23/5386

(57) ABSTRACT

An electronic device includes a first integrated circuit die, a support structure, and a second integrated circuit die and may include a spacer. The support structure includes a circuit element. The support structure has a thickness of at least 110 microns. The spacer or second integrated circuit die includes a conductor. The spacer or second integrated circuit die is disposed between the first integrated circuit die and the support structure. The conductor is electrically coupled to the integrated circuit die or the circuit element of the support structure. The electronic device provides more flexibility to a designer by allowing a circuit element or circuit that occupies a significant area to be in the support structure.

### FIELD OF THE DISCLOSURE

The present disclosure relates to electronic devices, and more particularly to electronic devices including integrated circuit dies and support structures.

### RELATED ART

An electronic device can include integrated circuit dies that are electrically coupled to one another. The thickness of each of the integrated circuit dies may be insufficient to provide acceptable mechanical support for the electronic device. A silicon carrier die can be physically coupled to one of the integrated circuit die to provide sufficient mechanical support. The silicon carrier die does not include any circuit element. Thus, the support structure may be used solely to provide sufficient mechanical support for the electronic device.

### SUMMARY OF DESCRIBED EMBODIMENTS

In an aspect, an electronic device can include a first integrated circuit die; a support structure including a first circuit element, wherein the support structure has a thickness of at least 110 microns; a second integrated circuit die being disposed between the first integrated circuit die and the support structure; and a first conductor electrically coupled to the second integrated circuit die and the first circuit element of the support structure.

In an embodiment, the electronic device further includes a spacer including a second conductor and being disposed between the first integrated circuit die and the support structure, wherein the second conductor of the spacer is electrically coupled to the first integrated circuit die or the first circuit element of the support structure.

In another embodiment, the first conductor is a through-substrate via disposed within the second integrated circuit die.

In still another embodiment, the first conductor is a bond pad that is coupled to a second circuit element disposed within the second integrated circuit die.

In yet another embodiment, the electronic device further includes a set of conductors, wherein the first integrated circuit die has a proximal surface and a distal surface opposite the proximal surface, the support structure is closer to the proximal surface of the first integrated circuit die than to the distal surface of the first integrated circuit die, and the set of conductors are disposed along the distal surface of the first integrated circuit die and configured to receive power and signals for the electronic device.

In a further embodiment, the first circuit element includes a capacitor, an inductor, a diode, or a voltage regulator, wherein the first circuit element has a first terminal and a second terminal, wherein the first terminal is coupled to a first power supply terminal, and the second terminal is coupled to a second power supply terminal.

In another aspect, an electronic device can include a first integrated circuit die; a support structure including a circuit element, wherein the support structure has a thickness of at least 110 microns; and a spacer including a first conductor, wherein the spacer is disposed between the first integrated circuit die and the support structure, and the first conductor is electrically coupled to the first integrated circuit die, the circuit element of the support structure, or both the first integrated circuit die and the circuit element of the support structure.

In an embodiment, the first integrated circuit die has a thickness less than 100 microns.

In another embodiment, the circuit element includes a capacitor, an inductor, a diode, or a voltage regulator.

In still another embodiment, the first conductor is a through-substrate via.

In yet another embodiment, the first integrated circuit die, the support structure, and the spacer are different die that include a same semiconductor base material.

In a further embodiment, the electronic device further includes a second integrated circuit die being disposed between the first integrated circuit die and the support structure; and a second conductor being disposed between the second integrated circuit die and the support structure, wherein the second conductor is electrically coupled to second integrated circuit die and the circuit element of the support structure.

In a particular embodiment, the first integrated circuit die includes a processor, and the second integrated circuit die is a memory device.

In another particular embodiment, the first integrated circuit die is electrically coupled to the second integrated circuit die.

In a further embodiment, the second integrated circuit die has a thickness less than 100 microns, and the thickness of the spacer is within 20 microns of the thickness of the second integrated circuit die.

In another particular embodiment, the electronic device further includes a set of conductors, wherein the first integrated circuit die has a proximal surface and a distal surface opposite the proximal surface, the support structure is closer to the proximal surface of the first integrated circuit die than to the distal surface of the first integrated circuit die, and the set of conductors are disposed along the distal surface of the first integrated circuit die and configured to receive power and signals for the electronic device.

In a further aspect, an electronic device can include a first integrated circuit die; a second integrated circuit die; and a support structure including a first level including a first circuit element and a conductor; and a second level including a second circuit element. The first level is disposed between the second integrated circuit die and the second level, and the support structure has a thickness of at least 110 microns. The second integrated circuit die is disposed between the first integrated circuit die and the support structure, and the conductor of the first level is electrically coupled to (1) the second circuit element of the second level and (2) the first integrated circuit die or the second integrated circuit die.

In an embodiment, the thickness of the support structure is in a range from 500 microns to 800 microns, and a thickness of each of the first integrated circuit die, the second integrated circuit die, and the first level is less than 100 microns.

In a particular embodiment, the second level has a thickness in a range from 110 microns to 1000 microns.

In another embodiment, the support structure includes a third level, wherein the third level does not include a circuit element.

### BRIEF DESCRIPTION OF THE DRAWINGS

Embodiments are illustrated by way of example and are not limited in the accompanying figures.

FIG. 1 includes a cross-sectional view of an electronic device that includes dummy dies and a carrier.

FIG. 2 includes a flow diagram of a process to manufacture an electronic device.

FIG. 3 includes an illustration of a cross-sectional view of an electronic device including two integrated circuit dies coupled to each other.

FIG. 4 includes an illustration of a cross-sectional view of the electronic device of FIG. 3 after coupling spacers to one of integrated circuit die.

FIG. 5 includes an illustration of a cross-sectional view of the electronic device of FIG. 4 after coupling a support structure to the spacers.

FIG. 6 includes an illustration of a top view of the electronic device of FIG. 5 illustrating locations of spacers and the upper integrated circuit die.

FIG. 7 includes an illustration of a cross-sectional view of the electronic device of FIG. 5 after forming conductive pillars and solder material along a surface of the lower integrated circuit die.

FIG. 8 includes an illustration of a cross-sectional view of a capacitor.

FIG. 9 includes an illustration of a cross-sectional view of a transistor structure.

FIG. 10 includes an illustration of a cross-sectional view of a diode.

FIG. 11 includes an illustration of a top view of a spiral inductor.

FIG. 12 includes an illustration of a top view of a helical inductor.

FIG. 13 includes an illustration of a cross-sectional view of a resistor.

FIG. 14 includes a circuit diagram of an energy converter.

FIG. 15 includes an illustration of a cross-sectional view of an electronic device without a spacer.

FIG. 16 includes an illustration of a cross-sectional view of an electronic device having a support structure with more than one level.

FIG. 17 includes an illustration of a cross-sectional view of an electronic device having a support structure with five levels.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application.

The term “circuit element” is intended to mean a capacitor, a diode, an inductor, a resistor, or a transistor. Any of the previously-mentioned circuit elements may provide a function by itself (a switch can be a transistor). A circuit includes a plurality of circuit elements that may be of the same type (e.g., an invertor includes two transistors) or different types (an RC circuit includes a resistor and a capacitor).

The term “electrically coupled” is intended to mean a connection, linking, or association of two or more electronic components, circuits, systems, or any combination of: (1) at least one electronic component, (2) at least one circuit, or (3) at least one system in such a way that a signal (e.g., current, voltage, or optical signal) may be partially or completely transferred from one to another. A non-limiting example of “electrically coupled” can include an electrical connection between two electronic components. In a circuit diagram, a node corresponds to an electrical connection between the electronic components. Thus, an electrical connection is a specific type of electrical coupling; however, not all electrical couplings are electrical connections. Other types of electrical coupling include capacitive coupling, resistive coupling, and inductive coupling.

Group numbers correspond to columns within the Periodic Table of Elements based on the International Union of Pure and Applied Chemistry (IUPAC) Periodic Table of Elements, version dated Dec. 1, 2018.

The term “metal” or any of its variants when referring to a material is intended to mean a material, whether or not a molecular compound, that includes an element that is within any of the Groups 1 to 12, and within Groups 13 to 16, an element that is along and below a line defined by atomic numbers 13 (Al), 31 (Ga), 50 (Sn), 51 (Sb), and 84 (Po). Metal does not include Si or Ge, by itself.

Lengths and widths are measured in directions along or parallel to a primary surface of a corresponding object. For an elliptical-shaped or oval-shaped object, a minor axis and a major axis are measured in directions along or parallel to a primary surface of the corresponding object. The major axis corresponds to a length, and the minor axis corresponds to a width. Height and thickness of a layer, a die, a structure, or other feature is measured in a direction perpendicular to the primary surface.

Unless explicitly stated to the contrary, the terms “horizontal,” “lateral,” and their variants are in a direction along or parallel to a primary surface of a corresponding object, and the terms “vertical” and its variants are in a directions perpendicular to the primary surface.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements in between the two elements.

The terms “comprises,” “comprising,” “includes,” “including,” “has,” “having,” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read such that the plurals include one or at least one and the singular also includes the plural, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) for the value are reasonable differences from the ideal goal of exactly as described. When values of a parameter are significantly different, such values are more than 10% different. When values of a parameter are different (e.g., less than, greater than, a numerical difference between values, or the like) and within manufacturing tolerances for commercial production, such values are insignificantly different.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

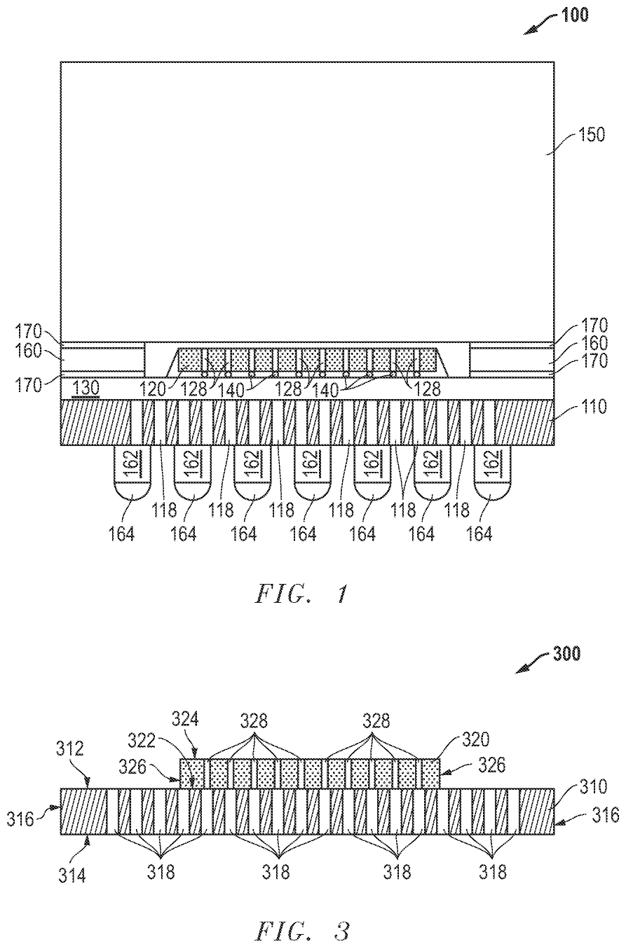

FIG. 1 illustrates a cross-sectional view of an electronic device 100 including a conventional carrier 150. The electronic device 100 includes a logic die 110 that is electrically connected to a memory die 120. The logic die 110 can include a processor, and the memory die 120 can include a memory cache used by the processor. Each of the dies 110 and 120 include through-substrate vias (TSVs) 118 and 128 that allow power and signals to be transmitting through the thicknesses of the dies 110 and 120. The dies 110 and 120 can be electrically coupled to each other via a redistribution layer (RDL) structure 130 and conductive bumps 140. Copper pillars 162 and solder bumps 164 are coupled to the logic die 110. With respect to external power, data and other signals are received by or transmitted from memory die 120 pass through the logic die 110.

Both dies 110 and 120 are relatively thin and can have a thickness less than 100 microns, for example in a range from 50 microns to 75 microns. From a top view, the logic die 110 occupies a larger area, as compared to the memory die 120, and is too thin to provide sufficient mechanical support for the electronic device 100.

The carrier 150 is used to provide sufficient mechanical support for the electronic device 100. The carrier 150 has approximately the same size (length and width) as the logic die 110. Dummy dies 160 are disposed between the logic die 110 and the carrier 150 and along the outer edges of the logic die 110 and carrier 150. The carrier 150 and the dummy dies 160 can be made from portions of silicon wafers. The thickness of the carrier 150 is in a range from 600 microns to 700 microns, and the thicknesses of dummy dies 160 are approximately the same as the thickness of the memory die 120. The dummy dies 160 are physically coupled to the logic die 110 and the carrier 150 using an adhesive 170. Neither the carrier 150 nor the dummy die 160 include any circuit element or any metallic conductive structure, such as a TSV or an interconnect.

The inventors have discovered that a support structure can be used in place of the carrier 150 and dummy dies 160 as illustrated in FIG. 1. From a top view, the support structure can occupy an area that is approximately the same as the larger die (if two levels of integrated circuit die) or the largest die (if three or more levels of integrated circuit die). The support structure can include a circuit element or a circuit that supplements or provides further functionality to an integrated circuit die within the electronic device. The concepts are better understood after reading the entire specification in conjunction with the appended drawings.

The concepts as presented herein are better understood after reading the entire specification in conjunction with the appended drawings.

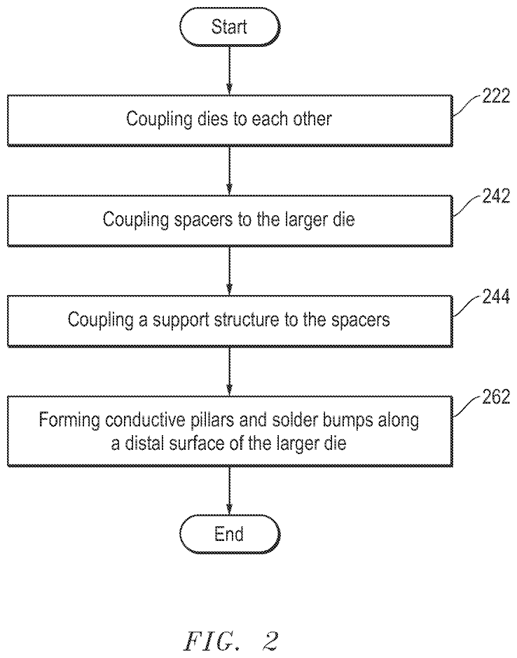

FIG. 2 includes an exemplary process flow that can be used in forming an electronic device in accordance with the following description. The manufacture of the electronic device is described with respect to the process flow in FIG. 2. Other process flows can be used and are addressed later in this specification. The process flow in FIG. 2 includes spacers; however, spacers are not required in all embodiments.

The process includes coupling the dies to each other at block 222 in FIG. 2. FIG. 3 includes an illustration of a partially completed electronic device 300 that includes an integrated circuit die 310 and an integrated circuit die 320.

Each of the dies 310 and 320 can be a microprocessor, a graphics processing unit (GPU), a digital signal processor (DSP), a memory device, an application integrated specific circuit (ASIC), or the like. Dies 310 and 320 can be the same type of device (e.g., both microprocessors, both GPUs, both memory devices, or both ASICs) or different types of devices. For example, the die 310 can be a microprocessor or a GPU, and the die 320 can be a memory device. As used herein, the types of devices are identified by their principal function. For example, a microprocessor can include a memory array; however, a microprocessor's principal function is not as a memory, and thus, a microprocessor is not a memory device. An integrated circuit that has a principal function of a memory, such as an SRAM die, a DRAM die, a flash memory die, etc., is a memory device. In a particular embodiment, the die 310 can be a microprocessor, and the die 320 can be a Level 3 (L3) cache memory device, and in another particular embodiment, the die 310 can be a Level 3 (L3) cache memory device, and the die 320 can be a microprocessor. In other embodiments, other combinations of integrated circuits can be used for the dies 310 and 320.

The die 310 has a proximal surface 312 and a distal surface 314 opposite the proximal surface 312, and the die 320 has a proximal surface 322 and a distal surface 324 opposite the proximal surface 322. From a top view, the die 310 occupies a larger area as compared to the die 320. Thus, the die 310 is referred to as the larger die, and the die 320 is referred to as the smaller die. Most, if not all, circuits and circuit elements are along the proximal surfaces 312 and 322 of the dies 310 and 320. The die 310 has outside edges 316 that extend between the proximal and distal surfaces 312 and 314, and the die 320 has outside edges 326 that extend between the proximal and distal surfaces 322 and 324.

The dies 310 and 320 include a semiconductor base material can include a monocrystalline Group 14 material including Si, SiC, Ge, or the like. As compared to each other, the dies 310 and 320 may have the same semiconductor base material or different semiconductor base materials. The die 310 has TSVs 318, and the die 320 has TSVs 328. TSVs are at least part of a set of conductors that can be disposed along proximal surfaces, distal surfaces, or both proximal and distal surfaces of the dies 310 and 320. TSVs described hereinafter can include a conductive material that is capable of being plated or deposited, such as Cu, Ni, Au, doped Si, W, or the like. Each of the dies 310 and 320 has a thickness less than 100 microns.

A metallization layer (not separately illustrated) can be part of either or both of the dies 310 and 320. The metallization layer can include silicon oxide layers and conductive layers that include metallic interconnects. The conductive layers include Al, Cu, Ni, Au, a metallic alloy, or the like. As compared to each other, the conductive layers can have the same metallic composition or different metallic compositions. The metallic interconnects are electrically coupled to circuits within each of the dies 310 and 320. For each of the dies 310 and 320, the metallization layer lies along the die's proximal surface, the die's distal surface, or both the die's proximal and distal surfaces. The metallization layer includes bond pads that are at an interconnect level farthest from circuits within the same die.

The dies 310 and 320 can be bonded to each other using a hybrid bonding technique. In an embodiment, insulating layers along proximal surfaces 312 and 322 of the dies 310 and 320 are bonded to each other. A thermal cycle can be performed such that the bond pads, TSVs, or combinations of bond pads and TSVs contact each other to make electrical contacts between the dies 310 and 320. The electrical connections with the hybrid bonds can include contact between bond pads of different dies, between a bond pad and a TSV of different dies, or between TSVs of different dies.

U.S. Pat. No. 11,011,495 (the '495 Patent) includes illustrations and a description of hybrid bonds within a semiconductor device and a multi-level metallization layer. The metallization layer as described herein is similar to the multi-level metallization layer of the '495 Patent. The '495 Patent is incorporated herein for its teachings of hybrid bonds and metallization layers.

In another embodiment, the bonding can include solder connections. The solder can include a conductive material that has a melting or flow point that is less than 300° C. The conductive material can be an alloy including Sn and one or more of In, Ag, Cu, or Au. Although Pb may be used in the solder, Pb is typically avoided due to environmental concerns. In a particular embodiment, the solder connections can be in the form of solder bumps to achieve a flip chip connection between the dies 310 and 320. If solder bumps are used, an underfill material can be used to fill the gap between the dies 310 and 320. The underfill material can include an epoxy and may include filler particles that include silica, alumina, AN, BN, or the like.

In FIG. 3, many of the TSVs 328 of the die 320 are illustrated as being directly above corresponding TSVs 318 of the die 310. A less resistive connection can be achieved when TSVs lie along the same vertical line that is perpendicular to proximal surfaces of dies 310 and 320. Thus, more power can be transmitted and less voltage loss can occur with such a configuration. In another embodiment, few or none of the TSVs 318 and 328 lie along the same vertical line. After reading this specification, skilled artisans will be able to design electrical connections within the electronic device to meet the needs or desires for a particular application.

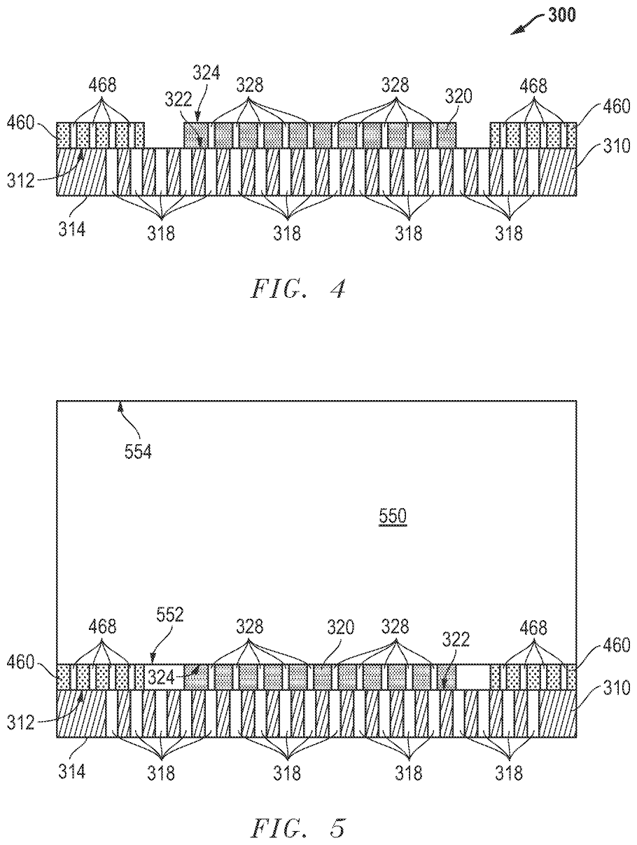

The process further includes coupling spacers to the larger die at block 242 in FIG. 2. FIG. 4 illustrates the electronic device 300 after spacers 460 are coupled to the die 310. Unlike the dummy dies 160 in FIG. 1, the spacers 460 include TSVs 468 that extend through the thickness of the spacers 460. The spacers 460 include a base material that can include a semiconductor or insulating material. The semiconductor material can include a monocrystalline Group 14 material including Si, SiC, Ge, or the like. The insulating material can include an oxide, a nitride, an oxynitride, or a polymer, such as an epoxy. The spacers 460 lie along outside edges 316 of the die 310. In an embodiment, a single spacer can lie adjacent to all the outside edges 316 of the die 310, and such single spacer can have an opening in which the die 320 is disposed. Regardless of whether a single spacer is used or a plurality of spacers is used, the spacer(s) can have a thickness that is within 10% of the thickness of the die 320. In the same or different embodiment, the thickness of the spacer(s) is within 50 microns of the thickness of the die 320. One or both sides of the spacers 460 can have a metallization layer as previously described with respect to the dies 310 and 320.

The electrical connections between the TSVs 468 and the die 310 can be any of types of electrical connections as previously described between the dies 310 and 320. A metallization layer can be used along surfaces of the spacers 460 and the die 320 where electrical connections are made. The metallization layer can include materials and components as previously described with respect to the metallization layer between the dies 310 and 320. In a particular embodiment, a hybrid bonding technique can be used to make the electrical connections. In such an embodiment, an insulating layer can lie along the surface of each spacer 460, where the TSVs 468 or bond pads are disposed within openings in the insulating layer. In another embodiment, the electrical connections can be in the form of solder connections. The electrical connections between the spacers 460 and the die 310 can be the same as or different from types of the electrical connections between the dies 310 and 320.

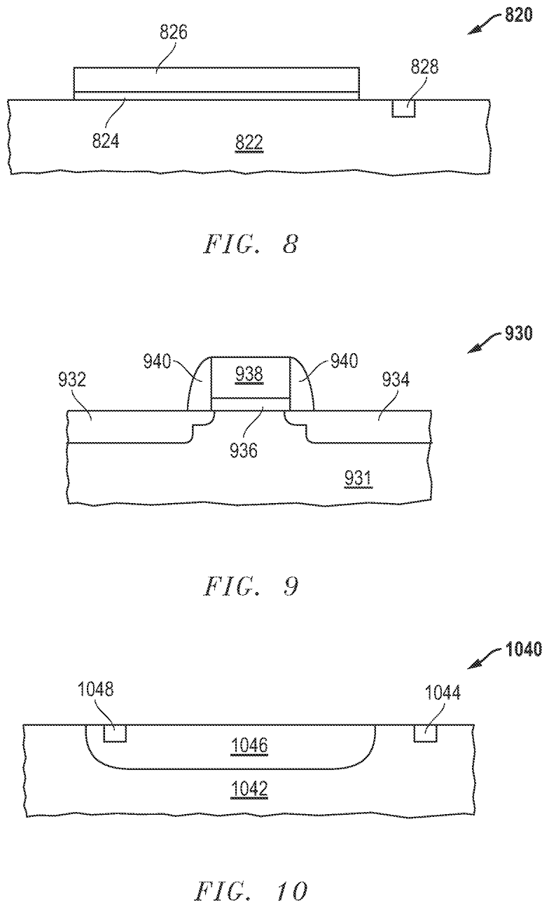

Within the spacers 460, each TSV 468 can be electrically connected to a circuit element within the die 310 or may be electrically connected to a TSV 318. In an embodiment, the TSVs 468 are electrically connected to subsequently-formed conductive pillars that will lie along the distal surface of the die 310 (illustrated in FIG. 7 as conductive pillars 762 along the bottom surface of the die 310). Such conductive pillars provide external connections for the electronic device and are configured to receive or transmit power or signals to or from an electrical device outside of the electronic device 300. When the TSVs at different elevations are arranged along a vertical line, power or signals can be transmitted more efficiently between such elevations.

The process includes coupling a support structure to the spacers at block 244 in FIG. 2. FIG. 5 illustrates the electronic device 300 after a support structure 550 is coupled to the spacers 460. The support structure 550 has a proximal surface 552 and a distal surface 554, where the die 320 is closer to the proximal surface 552 than to the distal surface 554. The die 320 and the spacers 460 are disposed between the support structure 550 and the die 310.

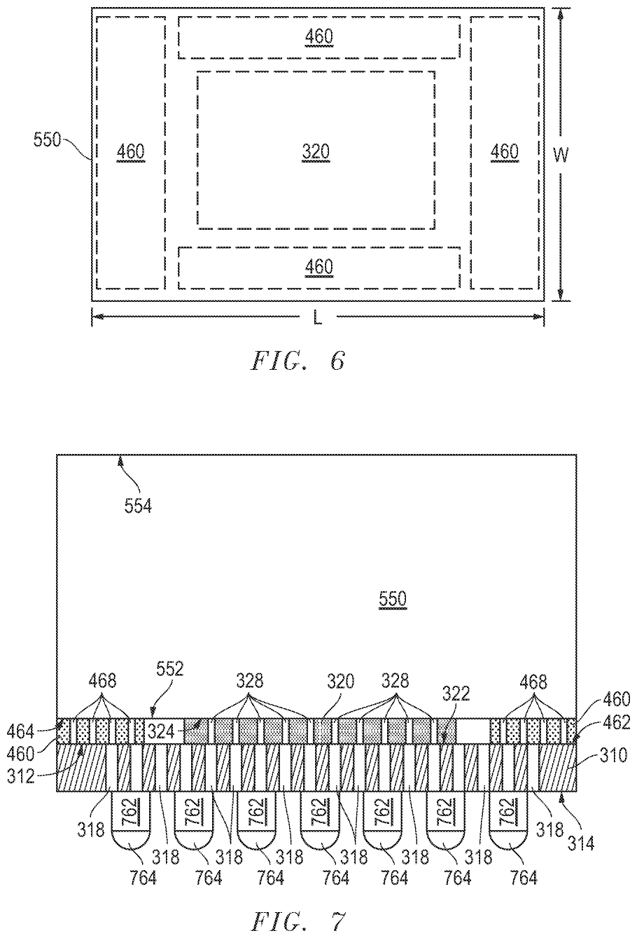

FIG. 6 includes a top view of the support structure 550. Dashed lines illustrate locations of spacers 460 and the die 320 that are under the support structure 550. The support structure 550 has a length, L, and a width, W. In an embodiment, the support structure 550 has a length that is within 10% of the length of the die 310 and has a width that is within 10% of the width of the die 310. In the same or different embodiment, the support structure 550 occupies an area that is within 10% of the area occupied by the die 310. The area occupied by each of the die 310 and the support structure 550 is greater than the combined area occupied by the die 320 and the spacers 460.

Similar to the carrier 150 in FIG. 1, the support structure 550 provides sufficient mechanical support of and an adequate thickness for the electronic device 300. In FIG. 5, the support structure 550 has a thickness of at least 110 microns. While a theoretical upper limit of the thickness can be very large, the thickness of the support structure 550 may be less than 2000 microns or no greater than 1000 microns. In an embodiment, the support structure 550 has a thickness in a range from 500 microns to 900 microns. The thickness of the support structure 550 can be selected for a particular application.

Unlike the carrier 150 in FIG. 1, the support structure 550 includes at least one circuit element. In an embodiment, the support structure 550 can include one circuit element or a plurality of circuit elements that make up a circuit. In the same or different embodiment, the support structure 550 can include a plurality of circuits. A circuit element or a circuit that provides an electrically-related support service to the die 310, the die 320, or both dies is well suited for the support structure. The proximal surface 552 of the support structure 550 can have a metallization layer as previously described with respect to the dies 310 and 320.

The support structure 550 can be electrically connected to one or more of the TSVs 468 of the spacers 460, one or more of the TSVs 328 of the die 320, bond pads of either or both of the spacers 460 or the die 320, or to any combination of at least one TSV and at least one bond pad of the spacers 460 and the die 320. Any of the electrical connections as previously described between the dies 310 and 320 can be used with the support structure 550 and any one or combination of the die 320 and spacers 460. In a particular embodiment, a hybrid bonding technique can be used to make the electrical connections. In another embodiment, the electrical connections can be in the form of solder connections. The electrical connections between the support structure 550 and one or both of the spacers 460 and the die 320 can be the same as or different from the electrical connections between the dies 310 and 320.

The process further includes forming conductive pillars and solder bumps along a distal surface of the larger die at block 262 in FIG. 2. FIG. 7 illustrates conductive pillars 762 and solder bumps 764 that are coupled to the die 310 and disposed along the distal surface 314 of the die 310. The conductive pillars 762 can be formed using a template layer (not illustrated) and plating or depositing conductive materials within openings that extend through the template layer. The conductive material can include Cu, Ni, Au, or the like. The template layer is removed, and if a seed layer was used, exposed portions of the seed layer are removed. Thus, the conductive pillars 762 include the conductive material, and if present, portions of the seed layer. A solder material is along ends of the conductive pillars 762 to form the solder bumps 764. The solder material can include any of the materials previously described with respect to the conductive bumps 340. In an embodiment, the solder bumps 764 can be in the form of Controlled Collapse Chip Connection (C4) bumps. In another embodiment, the solder bumps 764 are not present. External power, data, and other signals to be received by or transmitted for the electronic device 300 pass through the conductive pillars 762.

Physical designs of circuit elements are addressed before describing electrical functions that can be used with respect to the support structure 550.

Exemplary physical designs for circuit elements that can be used in the support structure 550 are illustrated in FIGS. 8 to 13. The support structure 550 can include a substrate that has the same semiconductor material as the substrates for the die 310 or 320.

FIG. 8 includes a cross-sectional view of a capacitor 820 that includes a doped region 822 as an electrode, a capacitor dielectric layer 824, and an electrically conductive member 826 as the other electrode. A doped contact region 828 may or may not be within the doped region 822. The doped contact region 828 allows an ohmic contact to be formed to the electrode that includes the doped region 822. The electrically conductive member 826 can be a heavily doped semiconductor, a metal (not an alloy or a compound), a metallic alloy, or a metallic compound. In another embodiment, not illustrated, a capacitor can include two electrodes separated by a capacitor dielectric layer, where the two electrodes are electrically isolated from a semiconductor substrate and have a composition as described with respect to the conductive member 826.

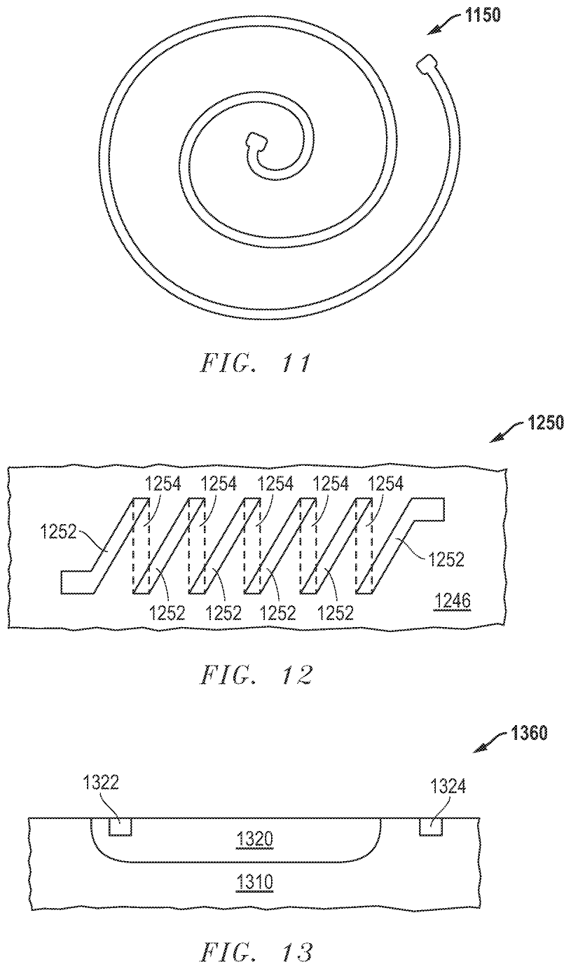

FIG. 9 includes a cross-sectional view of a transistor structure 930 that includes a well region 931, a source region 932, a drain region 934, a gate dielectric layer 936, a gate electrode 938, and sidewall spacers 940. The transistor structure 930 is an n-channel transistor or a p-channel transistor and is an enhancement-mode transistor or a depletion-mode transistor. In another embodiment, the transistor structure can be configured as a capacitor (the well region 931, the source region 932, and the drain region 934 are at the same voltage and act as a capacitor electrode, and the gate electrode 938 is the other capacitor electrode) or a gated diode (source region 932 and the gate electrode 938 are electrically connected to each other). In another embodiment (not illustrated), a transistor structure can be a bipolar junction transistor, or a junction field-effect transistor. In the same or different embodiment, a transistor structure can be a thin-film transistor or a vertical transistor.

FIG. 10 includes a cross-sectional view of a pn diode 1040 that includes a doped region 1042 and a doped region 1046, where the first and second doped regions 1042 and 1046 have opposite conductivity types. Depending on the dopant concentrations of the regions 1042 and 1046, one or both of doped regions 1042 and 1046 can have doped contact regions 1044 and 1048 to allow ohmic contacts to be formed to the doped regions 1042 and 1046. The doped region 1042 and contact region 1044 have the same conductivity type, and the doped region 1046 and the contact region 1048 have the same conductivity type. In an embodiment, the first doped region 1042 is an anode for the diode 1040, and the second doped region 1046 is a cathode for the diode 1040. In another embodiment where conductivity types are reversed, the first doped region 1042 is a cathode for the diode 1040, and the second doped region 1046 is an anode for the diode 1040. A Zener diode or a Schottky diode may be used instead of the pn diode 1040.

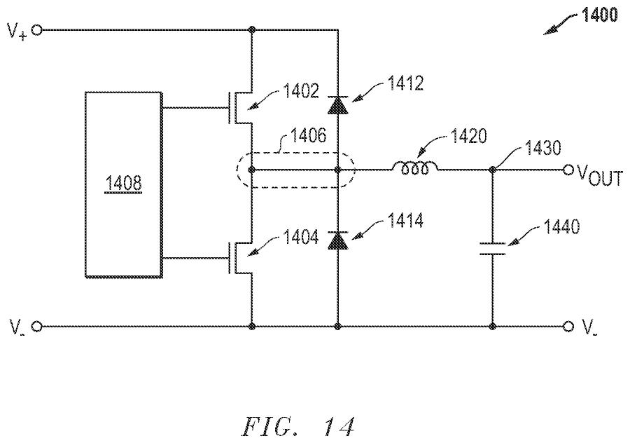

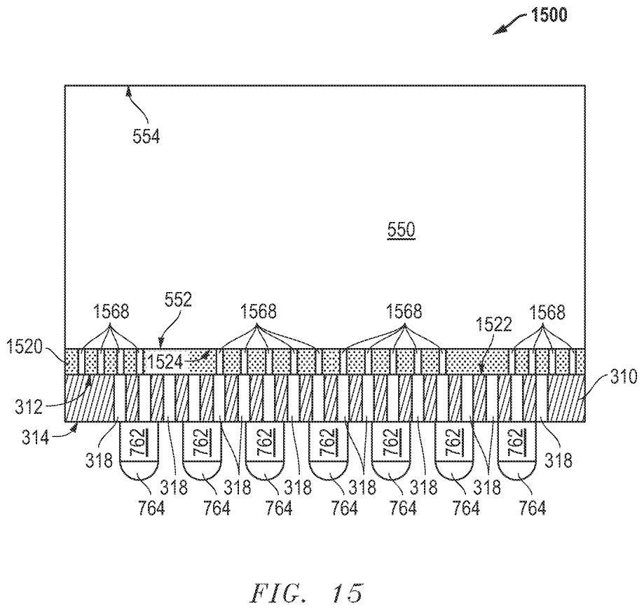

FIGS. 11 and 12 include top views of inductors. In FIG. 11, the inductor 1150 is a planar, spiral inductor. FIG. 12 includes a helical inductor 1250. The solid lines correspond to electrical conductors 1252 that overlie a dielectric layer 1246, and dashed lines correspond to electrical conductors 1254 that underlie the dielectric layer 1246. Other electrical conductors (not illustrated in FIG. 12) extend through the thickness of the dielectric layer 1246 and connect a pair of corresponding electrical conductors 1252 and 1254 to each other.

FIG. 13 includes a cross-sectional view of a resistor 1360 that includes a doped region 1320. The doped region 1320 can be within a semiconductor substrate 1310. Depending on the dopant concentration of the doped region 1320, doped contact regions 1322 and 1324 may be formed within the resistor to allow ohmic contacts to the resistor. In another embodiment, a resistor can be formed over a dielectric layer, as opposed to within the substrate 1310.

Many different designs of circuit elements have been described. The designs illustrated and described are exemplary and do not limit designs that can be used with the support structure 550.

The support structure 550 is well suited for a circuit element or a circuit that occupies a significant amount of area. Many different circuit elements and circuits can be used with the support structure 550. Below are some exemplary circuit elements and circuits that can be used with the support structure 550. Such exemplary circuit elements and circuits are intended to illustrate applications and not limit the scope of the appended claims.

A passive circuit element can be part of the support structure 550. A capacitor having an electrode coupled to a positive power supply terminal and the other electrode coupled to a negative power supply terminal helps to reduce voltage variations seen by components within the electronic device 300. For example, one of the capacitor electrodes is coupled to a VDD terminal, and the other capacitor electrode is coupled to a VSS or ground terminal. The capacitor may perform better with larger capacitor electrodes. The die 310, the die 320, or both may have such a capacitor, but the area occupied by the capacitor is limited is size. In some applications, the capacitor may require a larger die which reduces the number die on a wafer and has a corresponding lower yield due to a larger die size. The capacitor can be offloaded from the die 310, 320, or both dies to the support structure 550. A substantially larger capacitor can be used with the support structure 550. In another embodiment, a relative smaller capacitor may be retained within the die 310, 320, or both dies, and the larger capacitor of the support structure 550 is coupled in parallel with the relatively smaller capacitor in the die 310, 320, or both dies.

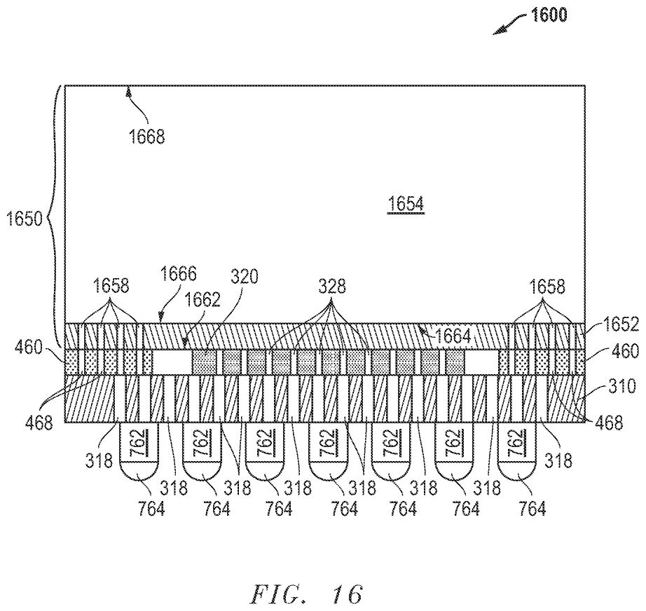

An energy converter can be part of the support structure. FIG. 14 includes a circuit for a voltage regulator 1400, which is a type of energy converter. A high-side transistor 1402 has a drain coupled to a positive power supply terminal and a source coupled to a drain of a low-side transistor 1404 at a switching node 1406 (illustrated with a dashed line in FIG. 14). A controller 1408 is coupled to the gates of the transistors 1402 and 1404. The body of the high-side transistor 1402 is coupled to the switching node 1406, and the body of the low-side transistor 1404 is coupled to the negative power supply terminal. A diode 1412 has a cathode coupled to the positive power supply terminal and an anode coupled to the switching node 1406, and a diode 1414 has a cathode coupled to the switching node 1406 and an anode coupled to the negative power supply. An inductor 1420 has a terminal coupled to the switching node 1406 and another terminal coupled to an output node 1430. A capacitor 1440 has an electrode coupled to the output node 1430 and another electrode coupled to the negative power supply terminal.

The amount of power that can be transmitted by a voltage regulator depends in part on the size of the voltage regulator. For example, more charge can flow through the transistors 1402 and 1404 with an increase of the effective channel widths of the transistors 1402 and 1404. Further, the cross-sectional area of interconnects may limit the amount of charge that can be provided to a load coupled to an output terminal and the negative power supply terminal.

The voltage regulator can be fabricated to be part of the support structure 550 and provide more design flexibility to provide sufficient current to meet the needs of the die 310, the die 320, or both dies. A voltage regulator on the die 310 or 320 may struggle to provide sufficient power to devices within dies 310 and 320 without occupying too much of the die area. The support structure 550 can be used to overcome the area limitations of the die 310, 320, or both dies. Similar to the large capacitor, the voltage regulator 1400 can replace or be used in conjunction with (power supply and output terminals connected in parallel) a voltage regulator on the die 310, the die 320, or both dies.

An inductor can be used to store energy and provide the stored energy at the same time or after storing the energy received by the inductor. The amount of charge that can be store by the inductor depends on the design of the inductor. The support structure 550 can allow a larger inductor or a more complicated design (e.g., a helical inductor) to be used without the complications of incorporating such inductor within the die 310 or the die 320.

The support structure 550 can include a diode. The diode can be relatively large area as compared to diodes on the dies 310 and 320. The diode can have a large interface between the anode and cathode to allow more charge to be stored when the diode is a reversed biased. The diode may or may not be used in conjunction with a relatively smaller diode on the die 310, the die 320, or both dies.

Other embodiments allow for different designs for the spacers 460 or even no spacers. The spacers 460 previously described focused more on providing electrical connections between the die 310 and the support structure 550. In another embodiment, the spacers 460 can include any of any one or more of the circuit elements or any one or more of the circuits previously described with respect to the support structure 550. Referring to FIG. 7, such circuit elements or circuits may lie along the proximal surface 462 of the spacers 460, along the distal surface 464 of the spacers 460, or both surfaces 462 and 464 of the spacers 460. In another embodiment, the spacers 460 can be any type of the integrated circuit die as previously described with respect to the integrated circuit dies 310 and 320. As compared to each other, one of the spacers 460 can have different electronic components as compared to one or more of the other spacers 460. For example, one of the spacers 460 can be an integrated circuit die, and another spacer 460 may only include a passive circuit element or a voltage regulator.

In another embodiment, the TSVs 468 may not be present. The circuit element or circuit within the support structure 550 is electrically connected to the die 320. Thus, one or more circuit elements or one or more circuits in either or both dies 310 and 320 can be coupled to the circuit element or circuit within the support structure 550 via an electrical connection between the support structure 550 and the die.

In the embodiment where a spacer 460 does not have any TSVs 468, any and all electronic component within such spacer 460 may lie along the proximal surface 462 of such spacer 460, and no electronic component and electrical connection lie along the distal surface 464 of such spacers 460. Alternatively, any and all electronic component within such spacer 460 may lie along the distal surface 464 of such spacer 460, and no electronic component and electrical connection lie along the proximal surface 462 of such spacers 460. In a further embodiment, one or more of the spacers 460 may be replaced by a dummy die 160 as illustrated in FIG. 1.

The bonding between the spacers 460 and each of the die 310 and the support structure 550 can depend on whether or not electrical connections are to be made. Where electrical connections are to be made along either or both surfaces 462 and 464 of one or more of the spacers 460, a metallization layer may lie along such surface. In such an embodiment, any of the electrical connections as previously described between the dies 310 and 320 can be used with the spacers 460 and any one or combination of the die 310 and support structure. A metallization layer can be used along surfaces of the support structure 55, the spacers 460 and the die 320 where electrical connections are made. The metallization layer can include materials and components as previously described with respect to the metallization layer between the dies 310 and 320. In a particular embodiment, a hybrid bonding technique can be used to make the electrical connections. In another embodiment, the electrical connections can be in the form of solder connections. The electrical connections between the spacers 460 and either or both of the die 310 and the support structure 550 can be the same as or different from the electrical connections between the dies 310 and 320.

In an embodiment where no electrical connection is to be made between one or more of the spacers 460 and the die 310 or the support structure 550, oxide layers may lie along the contacting surfaces, and fusion bonding may be used to bond together such spacer 460 and the die 310 or the support structure 550. When one or more dummy dies 160 are used instead of one or more of the spacers 460, oxide layers may lie along either or both of the contacting surfaces of the dummy die(s) 160, the die 310, and the support structure 550, and such surfaces can be bonded by fusion bonding. Alternatively, any fusion bond described in this paragraph can be replaced by an adhesion bond where an adhesive compound is disposed and contacts the contacting surfaces. Where an adhesive compound is used, an oxide layer may or may not be present at a contacting surface of any of the spacers 460 or any one of the dummy dies 160.

In a further embodiment, no spacer 460 and no dummy die 160 may be used. The integrated circuit die 320 and spacers 460 as illustrated in FIGS. 4 to 7 can be replaced by an integrated circuit die 1520 having a proximal surface 1522, a distal surface 1524, and TSVs 1568 extending through the thickness of the die 1520 as illustrated in FIG. 15. The die 1520 can be of any of the types of integrated circuit dies as previously described with respect to the dies 310 and 320. In the same or different embodiment, the length of the die 1520 has a length, L, and a width, W. In an embodiment, the die 1520 has a length that is within 10% of the length of the die 310, the support structure 550, or both and has a width that is within 10% of the width of the die 310, the support structure 550 or both. In the same or different embodiment, the die 1520 occupies an area that is within 10% of the area occupied by the die 310, the support structure 550, or both.

The electrical connections between the die 1520 and the die 310 and the support structure can be any of types of electrical connections as previously described between the dies 310 and 320. In an embodiment, a metallization layer may lie along each of the proximal and distal surfaces 1522 and 1524 of the die 1520. The metallization layer can include materials and components as previously described with respect to the metallization layer between the dies 310 and 320. In a particular embodiment, a hybrid bonding technique can be used to make the electrical connections. In another embodiment, the electrical connections can be in the form of solder connections. The electrical connections between the die 1520 and the die 310 and support structure 550 can be the same as or different from types of the electrical connections between the dies 310 and 320. Further, electrical connections between the dies 1520 and 310 may be different a different type of electrical connection as compared between the die 1520 and the support structure 550. For example, the electrical connections between the dies 1520 and 310 can be solder connections, and the electrical connections between the die 1520 and the support structure 550 may be hybrid bonds.

Skilled artisans will appreciate that may options are available regarding the spacers 460, and one or more of the spacers 460 can be replaced by a dummy die 160. In an embodiment, no spacer 460 and no dummy die 160 are used, such as illustrated in FIG. 15. After reading this specification, a device designer will be able to design the electronic device to meet the needs or desires for a particular application.

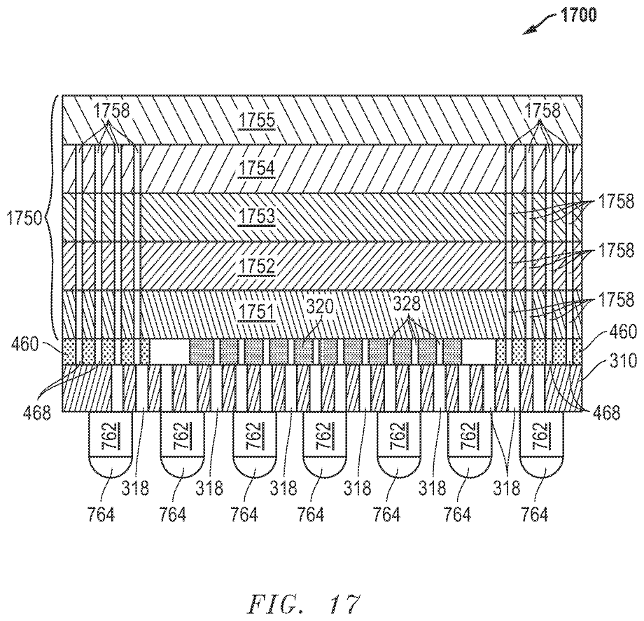

In another embodiment, a support structure can include more than one level that each includes a circuit element or a circuit. FIG. 16 includes a cross-sectional view of an electronic device 1600 that includes a support structure 1650 that includes a lower level 1652 and an upper level 1654. The lower level 1652 is disposed between the die 310 and the upper level 1654. The lower level 1652 has a proximal surface 1662 and a distal surface 1664, where the die 320 is closer to the proximal surface 1662 than to the distal surface 1664. The upper level 1654 has a proximal surface 1666 and a distal surface 1668, where the lower level 1652 is closer to the proximal surface 1666 than to the distal surface 1668.

In an embodiment, each of the lower level 1652 and upper level 1654 has a size that is similar to the die 310. In such an embodiment, each of the levels 1652 and 1654 occupies an area that is within 10% of the area of the die 310. The area occupied by each of the die 310 and the support structure 1650, including levels 1652 and 1654, is greater than the combined area occupied by the die 320 and the spacers 460. In the same or different embodiment, each of the levels 1652 and 1654 has a length that is within 10% of the length of the die 310 and has a width that is within 10% of the width of the die 310. As compared to each other, the lower and upper levels 1652 and 1654 can occupy the same amount of area or different amounts of area. The lower and upper levels 1652 and 1654 can have the same length or different lengths, and the lower and upper levels 1652 and 1654 can have the same width or different widths.

Just like the support structure 550, the support structure 1650 provides sufficient mechanical support of and an adequate thickness for the electronic device 1600. Thus, the support structure 1650 has a thickness of at least 110 microns. While a theoretical upper limit of the thickness can be large, the thickness of the support structure can be less than 2000 microns or no greater than 1000 microns. In an embodiment, the support structure 1650 has a thickness in a range from 500 microns to 900 microns.

The lower level 1652 has a thickness as described with respect to the dies 310 and 320 and spacers 460. The upper level 1654 can be thinner than the support structure 550, so that the overall thickness of the support structure 1650 is approximately the same as the support structure 550. The upper level 1654 has a thickness of at least 110 microns. While a theoretical upper limit of the thickness can be large, the thickness of the upper level 1654 can be less than 1900 microns. In an embodiment, the upper level 1654 has a thickness in a range from 400 microns to 800 microns. Each of the lower level 1652 and the upper level 1654 can include a substrate that has any of the semiconductor materials as the substrates for the die 310 or 320.

In an embodiment, the lower level 1652, the upper level 1654, or both levels can include a circuit element or a plurality of circuit elements that make up a circuit. In the same or different embodiment, the lower level 1652, the upper level 1654, or both levels can include a plurality of circuits. Most, if not all, of the circuits and circuit elements are along the proximal surfaces 1662 and 1666 of the levels 1652 and 1654. In another embodiment, at least some of the circuits and circuit elements can be along the distal surface 1664 of the lower level 1652. Referring to the voltage regulator in FIG. 14, the controller 1408 can be along the proximal surface 1666 of the upper level 1654, and all circuit elements (other than the controller 1408 illustrated in FIG. 14) are along the distal surface 1664 of the lower level 1652. Any of the circuit elements and circuits previously described with respect to the support structure 550 can be used with the lower level 1652, the upper level 1654, or both levels. In a further embodiment, the lower level 1652 can be an integrated circuit die of any of the types previously described with respect to the dies 310 and 320.

After reading this specification, skilled artisans will appreciate that other designs and configurations for the lower level 1652 can be used without deviating from the concepts described herein.

The lower level 1652 includes TSVs 1658 to allow the upper level 1654 to be electrically coupled to the lower level 1652, the die 320, or the die 310. The electrical connections between the lower level 1652 and any of the die 320, the spacers 460, and the upper level 1654 can be any of types of electrical connections as previously described between the dies 310 and 320. In an embodiment, a metallization layer may lie along each of the proximal and distal surfaces 1662 and 1664 of the lower level 1652 and along the proximal surface 1666 of the upper level 1654. In a particular embodiment, a hybrid bonding technique can be used to make the electrical connections. A metallization layer can be used along each of the contacting surfaces of the levels 1652 and 1654, the spacers 460, and the die 320 and where electrical connections are made. The metallization layer can include materials and components as previously described with respect to the metallization layer between the dies 310 and 320. In another embodiment, the electrical connections can be in the form of solder connections.

The electrical connections between the lower level 1652 and the die 320, the spacers 460, and upper level 1654 can be the same as or different from types of the electrical connections between the dies 310 and 320. Further, electrical connections between the lower level 1652 and the die 320, between the lower level 1652 and the spacers 460, and between the lower level 1652 and the upper level 1654 may be different types of electrical connections. For example, the electrical connections between the upper and lower levels 1652 and 1654 can be solder connections, and the electrical connections between the lower level 1652 and the die 320 and between the lower level 1652 and the spacers 460 may be hybrid bonds.

In another embodiment, the upper level 1654 does not include any circuit element or circuit. Thus, the upper level 1654 can be a carrier similar to the carrier 150 in FIG. 1. The previously described thicknesses for the upper level 1654 can be used to ensure the support structure 1650 has a desired overall thickness. In this embodiment, the lower level 1652 may have the same number, a different number, or even no TSVs 1658. Bond pads and interconnects (not illustrated) along the proximal surface 1662 of the lower level 1652 may be used to route power or signals from the die 320 or spacers 460 to a circuit element or circuit within the lower level 1652. Skilled artisans will be able to determine whether the lower level 1652 has TSVs 1658 and, if so, the number and location of the TSVs 1658 to meet the needs or desires for a particular application.

The electrical functional and design considerations for the support structure 1650 may be substantially the same as the support structure 550. As compared to the support structure 550, the support structure 1650 provides more design flexibility. In a particular embodiment, the upper level 1654 can include a circuit, which when operating, generates noise, emits electro-magnetic radiation, or otherwise interferes with the operation of a circuit within the die 310, the die 320, or both dies. The lower level 1652 can include a grounding plane or another electrically conductive plane at a fixed voltage or another feature to reduce the adverse effects to the die 310, the die 320 or both dies when the circuit in the upper level 1654 is operating.

In a further embodiment, a support structure includes more levels. FIG. 17 includes a cross-sectional view of a support structure 1750 that includes levels 1751, 1752, 1753, 1754, and 1755. Just like the support structure 550, the support structure 1750 provides sufficient mechanical support of and an adequate thickness for the electronic device 1700. Thus, the support structure 1750 has a thickness of at least 110 microns. While a theoretical upper limit of the thickness can be large, the thickness of the support structure can be less than 2000 microns or no greater than 1000 microns. In an embodiment, the support structure 1750 has a thickness in a range from 500 microns to 900 microns.

Each of the levels 1751, 1752, 1753, 1754, and 1755 has a primary surface and a distal surface opposite the primary surface. For each of the levels 1751, 1752, 1753, 1754, and 1755, the die 320 is closer to the primary surface than to the distal surface. All levels except the uppermost level 1755 include TSVs 1758.

Each of the levels 1751, 1752, 1753, 1754, and 1755 can have a size that is similar to the die 310. In an embodiment, each of the levels 1751, 1752, 1753, 1754, and 1755 occupies an area that is within 10% of the area occupied by the die 310. The area occupied by each of the die 310 and levels 1751, 1752, 1753, 1754, and 1755 within the support structure 1750 is greater than the combined area occupied by the die 320 and the spacers 460. In the same or different embodiment, each of the levels 1751, 1752, 1753, 1754, and 1755 has a length that is within 10% of the length of the die 310 and has a width that is within 10% of the width of the die 310. As compared to one another, the levels 1751 to 1755 can occupy the same amount of area or different amounts of area. As compared to one another, the levels 1751 to 1755 can have the same length or different lengths, and the levels 1751 to 1755 can have the same width or different widths.

Each of levels 1751, 1752, 1753, 1754, and 1755 can have any of the compositions and thicknesses as discussed with the lower level 1652 of the support structure 1650. As compared to one another, the levels 1751, 1752, 1753, 1754, and 1755 can have the same thickness or different thicknesses. Each of the levels 1751, 1752, 1753, 1754, and 1755 can have any circuit element or circuit as previously described with respect to the levels 1652 and 1654 of the support structure 1650. As the number of levels within a support structure increases, so does the flexibility in designing how electrical functions are to be provided by the support structure. Thus, more design flexibility can be seen with the support structure 1750 as compared to the support structure 1650, which has more design flexibility as compared to the support structure 550.

Each of the levels 1751, 1752, 1753, and 1754 includes TSVs 1758 to allow each overlying level within the support structure 1750 to be electrically coupled to an underlying level within the support structure 1750, the spacers 460, the die 320, or the die 310. The electrical connections can be any of types of electrical connections as previously described between the dies 310 and 320. In an embodiment, a metallization layer may lie along each of the surfaces of the levels of the support structure 1750 where electrical connections are made. The metallization layer can include materials and components as previously described with respect to the metallization layer between the dies 310 and 320. In a particular embodiment, a hybrid bonding technique can be used to make some or all of the electrical connections. In another embodiment, some or all of the electrical connections can be in the form of solder connections. Further, electrical connections between any level and another level and between the level 1751 and the die 320 or the spacers 460 can be different types of electrical connections.

In another embodiment, the level 1755 does not include any circuit element or circuit. Thus, the level 1755 can be a carrier similar to the carrier 150 in FIG. 1. The previously described thicknesses for the level 1755 can be used to ensure the support structure 1750 has a desired overall thickness. In this embodiment, the level 1754 may have the same number, a different number, or even no TSVs 1758. Bond pads and interconnects (not illustrated) along the proximal surface of the level 1754 may be used to route power or signals from the level 1753 to a circuit element or circuit within the level 1754. Skilled artisans will be able to determine whether the level 1755 has TSVs 1758 and, if so, the number and location of the TSVs 1758 to meet the needs or desires for a particular application.

In a further embodiment, at least one of level 1751, 1752, 1753, or 1754 may not include any circuit element or circuit. Such level can include a TSV 1758 to allow electrical connections between immediately adjacent levels. For example, level 1753 may not include any circuit or circuit element. The TSVs 1758 in the level 1753 can still be present to allow power or a signal to be transmitted between the levels 1752 and 1754, where the level 1754 includes at least one circuit element or circuit. The thickness of a level 1751, 1752, 1753, or 1754 that does not include a circuit element or a circuit may have a thickness is thicker or thinner than those previously described with respect to the lower level 1652 in FIG. 16; however, the support structure 1750 has an overall thickness as previously described.

Many alternative embodiments have been described with respect to the spacers 460. In addition to circuit alternatives, one or more of the spacers 460 can be replaced by one or more dummy die 160, or the combination of the spacers 460 and the die 320 can be replaced by the die 1520. Such alternatives may also be used with the electronic devices 1600 and 1700.

FIG. 2 includes an exemplary process flow. A different process flow may be used without deviating from the concepts as described herein. For example, the spacers 460 can be coupled to support structure before the combination of the spacers 460 and support structure are coupled to the die 310. When more than one level is present within the support structure, less than all of the levels within the support structure may be coupled to spacers 460 before the remaining level or levels are coupled to level or levels that are already coupled to the spacers 460. Further, the support structure 1650 or 1750 can be fabricated before coupling the support structure 1650 or 1750 to the spacers 460.

Embodiments described herein replace a physical structure, such as a carrier that provides no electrical function, with a support structure that provides an electrical function in addition to mechanical support and providing an adequate thickness. The support structure can occupy substantially the same area and have substantially the same outer dimensions (length, width, and height) as compared to the carrier. Thus, replacing the carrier with the support structure can be performed without adding complications to subsequent manufacturing related to a finished electronic device, such as completing assembly of the electronic device, such as packaging, or coupling the electronic device to a printed wiring board, a packaging substrate, or the like.

From an electrical function standpoint, the support structure is well suited for a passive circuit element or a circuit that occupies a significant area. Further, the support structure includes a circuit element or circuit that can principally provide an electrical support function to the die 310 or 320. An energy converter, such as a voltage regulator, is an example of a circuit that can occupy a significant amount of area and provide an electrical support function to the die 310, the die 320, or both dies. The support structure can include a circuit element or circuit that may adversely interfere with the operation of the die 310, the die 320, or both dies if such circuit element or circuit was within the die 310 or 320. Other reasons may exist for providing a circuit element or a circuit within the support structure, as opposed to the die 310, 320, or both. After reading this specification, skilled artisans will appreciate that they now have greater design flexibility where a support structure provide an electrical function for the electronic device.

Some embodiments have extensive use of TSVs and do not require a redistribution layer. This embodiment allows for less resistive connections between different components that are within different die, spacers, or portions of the support structure. More power and voltage loss can be seen with such a configuration.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device comprising:
a first integrated circuit die;
a support structure including a first circuit element, wherein the support structure has a thickness of at least 110 microns;
a second integrated circuit die being disposed between the first integrated circuit die and the support structure; and
a first conductor electrically coupled to the second integrated circuit die and the first circuit element of the support structure.

2. The electronic device of claim 1, further comprising a spacer including a second conductor and being disposed between the first integrated circuit die and the support structure, wherein the second conductor of the spacer is electrically coupled to the first integrated circuit die or the first circuit element of the support structure.

3. The electronic device of claim 1, wherein the first conductor is a through-substrate via disposed within the second integrated circuit die.

4. The electronic device of claim 1, wherein the first conductor is a bond pad that is coupled to a second circuit element disposed within the second integrated circuit die.

5. The electronic device of claim 1, further comprising a set of conductors, wherein:
the first integrated circuit die has a proximal surface and a distal surface opposite the proximal surface,
the support structure is closer to the proximal surface of the first integrated circuit die than to the distal surface of the first integrated circuit die, and
the set of conductors are disposed along the distal surface of the first integrated circuit die and configured to receive power and signals for the electronic device.

6. The electronic device of claim 1, wherein the first circuit element includes a capacitor, an inductor, a diode, or a voltage regulator, wherein the first circuit element has a first terminal and a second terminal, wherein the first terminal is coupled to a first power supply terminal, and the second terminal is coupled to a second power supply terminal.

7. An electronic device comprising:
a first integrated circuit die;
a support structure including a circuit element, wherein the support structure has a thickness of at least 110 microns; and
a spacer including a first conductor, wherein the spacer is disposed between the first integrated circuit die and the support structure, and the first conductor is electrically coupled to the first integrated circuit die, the circuit element of the support structure, or both the first integrated circuit die and the circuit element of the support structure.

8. The electronic device of claim 7, wherein the first integrated circuit die has a thickness less than 100 microns.

9. The electronic device of claim 7, wherein the circuit element includes a capacitor, an inductor, a diode, or a voltage regulator.

10. The electronic device of claim 7, wherein the first conductor is a through-substrate via.

11. The electronic device of claim 7, wherein the first integrated circuit die, the support structure, and the spacer are different die that include a same semiconductor base material.

12. The electronic device of claim 7, further comprising:
a second integrated circuit die being disposed between the first integrated circuit die and the support structure; and
a second conductor being disposed between the second integrated circuit die and the support structure, wherein the second conductor is electrically coupled to second integrated circuit die and the circuit element of the support structure.

13. The electronic device of claim 12, wherein the first integrated circuit die includes a processor, and the second integrated circuit die is a memory device.

14. The electronic device of claim 12, the first integrated circuit die is electrically coupled to the second integrated circuit die.

15. The electronic device of claim 12, wherein:
the second integrated circuit die has a thickness less than 100 microns, and
the thickness of the spacer is within 20 microns of the thickness of the second integrated circuit die.

16. The electronic device of claim 12, further comprising a set of conductors, wherein:
the first integrated circuit die has a proximal surface and a distal surface opposite the proximal surface,
the support structure is closer to the proximal surface of the first integrated circuit die than to the distal surface of the first integrated circuit die, and
the set of conductors are disposed along the distal surface of the first integrated circuit die and configured to receive power and signals for the electronic device.

17. An electronic device comprising:
a first integrated circuit die;
a second integrated circuit die; and
a support structure including:
a first level including a first circuit element and a conductor; and
a second level including a second circuit element,
wherein:
the first level is disposed between the second integrated circuit die and the second level, and
the support structure has a thickness of at least 110 microns;
wherein:
the second integrated circuit die is disposed between the first integrated circuit die and the support structure, and
the conductor of the first level is electrically coupled to (1) the second circuit element of the second level and (2) the first integrated circuit die or the second integrated circuit die.

18. The electronic device of claim 17, wherein:
the thickness of the support structure is in a range from 500 microns to 800 microns, and
a thickness of each of the first integrated circuit die, the second integrated circuit die, and the first level is less than 100 microns.

19. The electronic device of claim 18, wherein the second level has a thickness in a range from 110 microns to 1000 microns.

20. The electronic device of claim 17, wherein the support structure includes a third level, wherein the third level does not include a circuit element.
